(19) United States
(12) Patent Application Publication
(10) Pub. No.: US 2003/0128022 A1
(43) Pub. Date: Jul. 10, 2003

(54) Method of testing an integrated circuit by simulation

(76) Inventors: Laurent Souef, Montauroux (FR); Emmanuel Solari, Le Belvedere (FR); Soenke Rogge, Hamburg (DE); Rainer Kytzia, Hamburg (DE); Michael Wittke, Pinneberg (DE)

Correspondence Address: PHILIPS ELECTRONICS NORTH AMERICAN CORP, 580 WHITE PLAINS RD, TARRYTOWN, NY, 10591, US

(21) Appl. No.: 10/324,765

(22) Filed: Dec. 20, 2002

(30) Foreign Application Priority Data
Dec. 28, 2001 (FR) 0116996

(51) Int. Cl. G01R 25/00

(52) U.S. Cl. 324/121 E

(57) ABSTRACT

The present invention relates to an integrated circuit test method, said method using at least one test vector comprising serialized input (SHIFT_IN) and output values. It is characterized in that it comprises the following steps:

setting the circuit in the serialization mode at the start of a clock cycle (CLK),

applying serialized input values (SHIFT_IN) of the test vector (V) in parallel to the selectors (S),

loading said serialized input values (SHIFT_IN) in parallel into said simple flip-flops (FF) associated with said selectors (S),

setting the circuit in the normal mode,

capturing serialized result values (SHIFT_RES) in the flip-flops (FF),

recovering said serialized result values (SHIFT_RES) in said flip-flops (FF) in parallel and comparing them with the serialized output values (SHIFT_OUT) of the test vector (V).

The present invention relates to an integrated circuit test method intended to function according to a normal mode and a serialization mode, said circuit comprising a clock, simple flip-flops, and associated selectors, said method using at least one test vector comprising serialized input and output values.

It finds a particular application in the design of an integrated circuit.

In order to test integrated circuits, various techniques are used such as the so-called “scan test” techniques which make it possible to tackle the circuit in the form of combinatorial blocks or combinatorial logic. In these techniques, the circuit is designed so as to function according to two cycles, a functional cycle corresponding to an application phase and a test cycle corresponding to a test phase, said test cycle comprising a normal mode and a serialization mode also known as shift mode. The circuit comprises in particular inputs, flip-flops, selectors, and interconnection points which, in shift mode, form a set of shift registers referred to as a scan chain, and a combinatorial logic. In shift mode, serialized input values of the test vector can be loaded within the flip-flops in order to test said circuit, said flip-flops being controlled by one and the same common clock. The serialized input values propagate within the combinatorial logic. After return to normal mode, a result is recovered which is compared with the serialized output values of the test vector.

The serialized input values of the vector can be loaded in parallel into the flip-flops by virtue of a simulator followed by a step of shifting said values in order to test the flip-flops, as described by the U.S. Pat. No. 5,574,853 filed on Jan. 3, 1994.

Although this state of the art makes it possible to load input values of the test vector more rapidly and to test the circuit on a functional level, it does not make it possible to test the serialization mode in itself, nor the functioning of the selectors, nor the functioning of the clock.

Thus one technical problem to be resolved by the present invention is to propose an integrated circuit test method intended to function in a normal mode and a serialization mode, said circuit comprising a clock, simple flip-flops, and associated selectors, said method using at least one test vector comprising serialized input and output values, which makes it possible to effectively validate the serialization mode, the selectors, and the circuit clock, whilst reducing the time taken by the simulation.

One solution to the technical problem posed is characterized in that the test method according to the present invention comprises the steps of:

setting the circuit in the serialization mode at the start of a clock cycle,

applying serialized input values of the test vector in parallel to the selectors,

loading said serialized input values in parallel into said simple flip-flops associated with said selectors,

setting the circuit in the normal mode,

capturing serialized result values in the flip-flops,

recovering said serialized result values in said flip-flops in parallel and comparing them with the serialized output values of the test vector.

According to a non-limiting embodiment, the test vector also comprises functional input values and functional output values.

According to a non-limiting embodiment, the integrated circuit test method also comprises a step of applying functional input values of the test vector to the circuit, said step being performed before the circuit is set in the normal mode.

According to a non-limiting embodiment, the integrated circuit test method also comprises a step of recovering at the same time result functional values on the circuit and comparing said values with functional output values of the test vector, said step being performed after the circuit is set in the normal mode.

Thus, as will be seen in detail later, such a method makes it possible, by virtue of the first step, to verify whether a transition between the normal mode and the serialization mode takes place without error. In addition, by applying values to the selectors and applying clock pulses, it is also checked that said selectors and said clock are functioning correctly.

The invention will be further described with reference to embodiments shown in the drawings to which, however, the invention is not restricted.

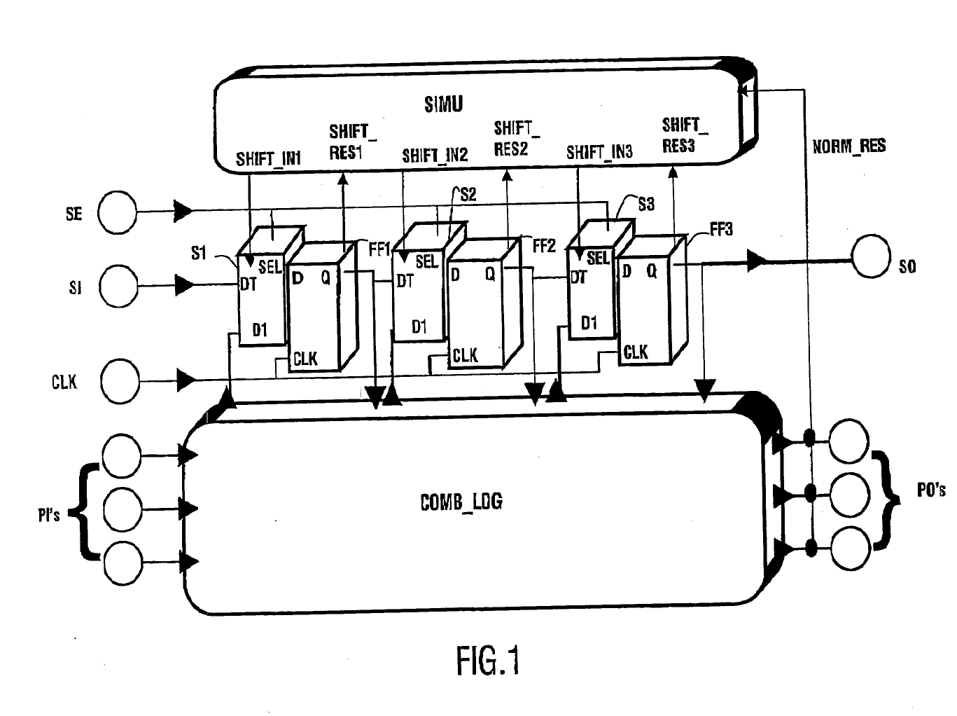

FIG. 1 illustrates schematically an architecture of an integrated circuit used by the method according to the invention,

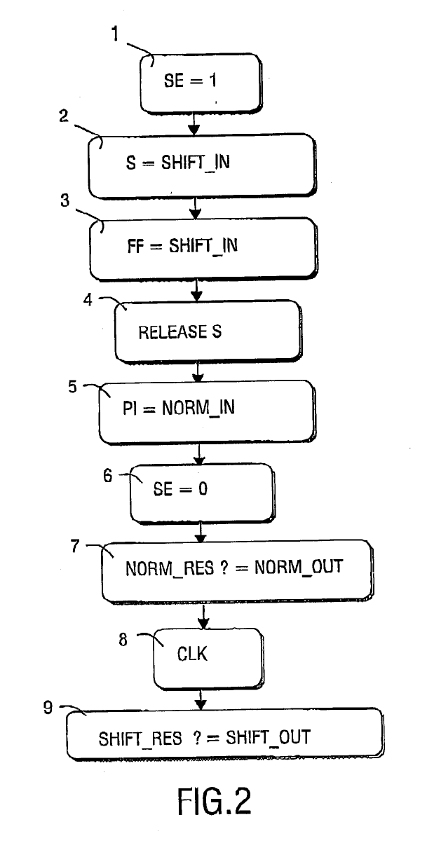

FIG. 2 is a flowchart of the method according to the invention, and

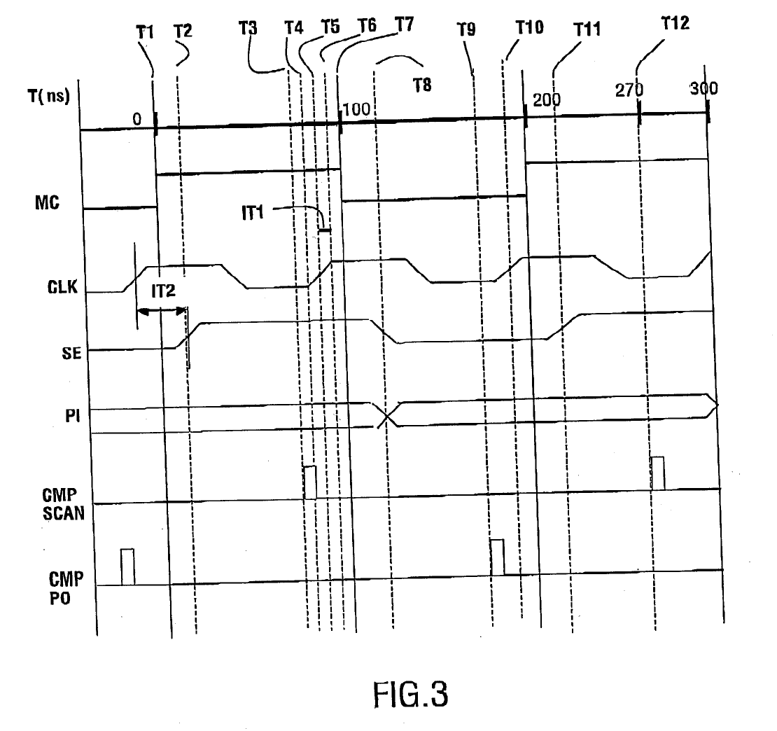

FIG. 3 is a synchronization diagram for various signals generated or used by the method of FIG. 2 during a simulation.

The present disclosure of the invention relates to an integrated circuit test method. During the manufacture of an integrated circuit, there are two main steps to be performed: a step of designing the circuit in particular according to functions specified by a customer, a step commonly referred to as the design step, and a manufacturing step. In order to ensure that the circuit will indeed be able to be tested physically during the manufacturing, step by a tester, said test method is applied to an integrated circuit by means of a simulation of the integrated circuit during the design step by a simulator SIMU. The integrated circuit is modeled and test vectors are applied by simulation to said-modeled circuit, as will be seen subsequently.

The integrated circuit comprises a functional cycle and a test cycle. The circuit comprises test elements or a scan chain such as flip-flops, selectors and input and output pins. The integrated circuit is of a type as illustrated in FIG. 1. In a test cycle, the integrated circuit has two modes, a normal mode and a serialization mode known as shift mode, in which all the flip-flops and selectors are interconnected in order to form one or even more shift registers or scan chain. Said circuit also comprises a combinatorial logic COM_LOG.

In the example in FIG. 1, the flip-flops in the scan chain are scan flip-flops MUX_FF comprising simple flip-flops FF, here three flip-flops FF1, FF2 and FF3, and selectors S, here three selectors S1, S2 and S3, a selector S being associated with each simple flip-flop FF. The circuit also comprises a clock CLK preferably common to the flip-flops MUX_FF, a control pin SE, an input test pin SI, an output test pin SO, and functional input PI and output PO pins. The functional input PI and output PO pins are connected to the combinatorial logic COM_LOG.

The combinatorial logic COM_LOG and the scan chain form an assembly which carries out functions required by a customer.

The simple flip-flops FF are preferably of the rising-edge sensitive synchronous D type and comprise a truth table as follows.

| CLK | D | Q | \overline{Q} |
|---|---|---|---|
| ↑ | 0 | 0 | 1 |
| ↑ | 1 | 1 | 0 |
| 0 | X | Qₙ₋₁ | \overline{Q}ₙ₋₁ |
| 1 | X | Qₙ₋₁ | \overline{Q}ₙ₋₁ |

FIG. 1 depicts solely the output Q which concerns us.

The input D is copied on the output Q at each rising edge of the clock CLK. A selector S which is associated with each flip-flop FF precedes said flip-flop and thus makes it possible to select an input which drives the associated flip-flop FF. Thus a selector S comprises two inputs DT and D1 for driving the associated flip-flop FF and a control input SEL for making a choice between the two inputs DT or D1 on said selector. A selector S thus comprises a truth table as follows.

| SEL | Output |
|---|---|
| 0 | D1 |
| 1 | DT |

The control inputs SEL of the selectors S are connected to the control pin SE. The first input DT1 of the first selector S1 is connected to the test pin SI.

In order to check that the design of the circuit does not include any error, it is necessary to test all the above elements in the integrated circuit. To this end, test vectors V are used. A test vector V comprises four sets of values. The first set contains serialized input values or shift input values SHIFT_IN which are applied as an input in the scan flip-flops MUX_FF. These shift input values make it possible to test said scan flip-flops and make it possible to apply input stimuli to the combinatorial logic COM_LOG of the circuit, as will be seen below. The second set contains functional input values NORM_IN which are applied to the functional inputs PI of the circuit. The third set contains serialized output values or shift output values SHIFT_OUT which will be compared with shift result values SHIFT_RES issuing from the combinatorial logic COM_LOG. The fourth set contains functional output values NORM_OUT which make it possible to make a comparison with functional result values NORM_RES, as will be seen below.

The test is carried out in accordance with the following steps.

In a 1^{st} step MOD_SHIFT), the circuit is set in the shift mode at the start of a clock cycle CLK. The control pin SE takes the logic 1 value. The scan flip-flops MUX_FF are then interconnected in the form of a shift register which has as its input the input DT1 of the circuit, said input being connected to the input pin SI, and has as its output the output Qn connected to the output pin SO. Optionally, it is possible to add a multiplexer to the output pin SO.

Unlike the state of the art presented in the preamble, this first step has the advantage of verifying that the control pin SE is indeed connected and that the transition between normal mode and shift mode takes place correctly.

Thus, for example, if the control pin SE is incorrectly connected in the circuit, it has a great chance of going to zero, and subsequently the shift register structure would be modified thereby so that wrong output values would be obtained at the output of the circuit.

In the state of the art, as values are forced directly into the simple flip-flops FF, even if the control pin SE is incorrectly connected, this will not be noticed.

Consequently, by making the value of the control pin SE vary, the impact of this pin on the design of the circuit is checked, unlike the tests of the state of the art in which the value of the control pin does not vary, i.e. where it is always either at 1 or at 0.

In a 2^{nd} step FORCE), shift input values SHIFT_IN of a test vector V are applied to the inputs DT of the selectors S of the scan flip-flops MUX_FF in parallel by means of the simulator SIMU.

This step has the advantage of no longer entering shift input values by shifting in the scan chain by giving clock pulses CLK until all the bits of said values are in the correct place. Consequently a considerable saving in time is achieved with regard to the simulation, on average by a factor varying from 100 to 1000. This factor is approximately equal to the number of scan flip-flops MUX_FF in the scan chain, said number representing a length of scan chain.

In a 3^{rd} step LOAD), said shift input values SHIFT_IN are loaded into said simple flip-flops FF, in parallel. To this end, a first clock pulse CLK is applied in order to trigger the loading. The input D of the first simple flip-flop FF1 contains the first shift input value SHIFT_IN1 of the test vector V. The input D of the second flip-flop FF2 contains the second shift input value SHIFT_IN2 of the test vector V, the input D of the third flip-flop FF3 contains the third shift input value SHIFT_IN3 of the test vector V, and so on. The entire scan chain is filled in a single clock pulse CLK.

This step has the advantage of testing the clock CLK. This is because, should the clock CLK be wrongly connected, this would be seen since the values captured subsequently in the scan flip-flops MUX_FF would be wrong, and the result obtained at the output would also be wrong.

In addition, this step combined with step 2 makes it possible to test the selectors S. This is because, should a selector S fail to work, this error would be seen since the shift input value SHIFT_IN propagated in the associated flip-flop FF would be wrong, the value captured in the corresponding scan flip-flop MUX_FF would also be wrong, as well as the result obtained at the output.

In a 4^{th} step RELEASE), the simulator releases the forced values in the inputs DT of the selectors S. The outputs Q of each simple flip-flop FF propagate in the combinatorial logic COM_LOG.

In a 5^{th} step ENTER_PI), test functional input values NORM_IN are applied to the functional input pins PI of the circuit.

In a 6^{th} step MOD_NORM), the circuit is set in the normal mode in order to subsequently capture functional values of the current normal mode in the scan flip-flops MUX_FF. For this purpose, the control pin SE takes the logic value 0.

The steps 5 and 6 are preferably performed at the same time.

In a 7^{th} step CMP_PO), functional result values NORM_RES are recovered at the output of the functional output pins PO of the circuit, in parallel by virtue of the simulator SIMU, and are compared with the functional output values NORM_OUT of the test vector V tested.

In an 8^{th} step CAPTURE), a clock pulse CLK is given in order to capture the correct values in the scan flip-flops MUX_FF. Thus the shift result values SHIFT_RES which are recovered in the inputs DI of the selectors of the flip-flops MUX_FF (the inputs D of the simple flip-flops FF are connected to the inputs D1 of the associated selectors S) and which are subsequently recovered in the inputs D of the scan flip-flops MUX_FF, propagate on the respective outputs Q of said scan flip-flops MUX_FF.

It should be noted that advantageously the 7^{th} step COMP_PO is performed before the 8^{th} step CAPTURE in order to prevent the simple flip-flops FF from sending signals to the combinatorial logic COM_LOG and destroying any values situated in the functional output pins PO.

Thus steps 5 to 8 verify the correct functioning of the scan flip-flops MUX_FF, and also of the combinatorial logic by the comparison of PO.

In a 9^{th} step CMP_SCAN), the shift result values SHIFT_RES in the outputs Q of the scan flip-flops MUX_FF are recovered, in parallel by virtue of the simulator SIMU, and are compared with the shift output values SHIFT_OUT of the test vector V.

This step makes it possible to save time during the test. This is because it avoids applying as many clock pulses CLK as are is necessary for outputting by shifting all said shift result values thus obtained in the simple flip-flops.

Preferably, this comparison is made during a shift mode, i.e. after the circuit has been reset in shift mode (SE=1).

The method is preferably implemented in the order of the steps presented above.

Thus the set of steps of the method according to the invention has the advantage of testing the combinatorial logic COMB_LOG of the circuit and the components of the scan chain whilst reducing the time necessary for such a test.

The steps mentioned above are preferably executed by the simulator SIMU in accordance with to a synchronization depicted in FIG. 3. This synchronization makes it possible to test the transitions from normal mode to shift mode on only two clock cycles CLK for each test vector V tested.

The tester has a basic cycle MC. By way of information, it is depicted in FIG. 3. At time t1, the tester enters a new test cycle.

At time t2, the 1^{st} step SHIFT_MOD) is performed. The shift mode is activated and the control pin SE is activated at 1.

At time t4, the 2^{nd} step FORCE) is performed. The shift input values SHIFT_IN of a test vector are forcibly applied to the inputs DT of the selectors S by means of the simulator SIMU. Preferably, as indicated in the example in FIG. 3, said values are forcibly applied before the rising edge of the next clock pulse CLK, in order to capture the correct values subsequently, those which have been “forced”.

At time t5, the 3^{rd} step LOAD) is performed. The shift input values SHIFT_IN are loaded into the simple flip-flops FF by means of the selectors S by giving a clock pulse CLK.

At time t6, the 4^{th} step RELEASE) is performed. The inputs DT of the selectors S are released. This step is performed preferably just after the rising edge of the clock pulse CLK, here approximately 1 ns after the LOAD step, i.e. prior to the step ENTER_PI. Thus, the release is not performed on a transition of a clock rising edge CLK. There is a first time interval IT1 between the loading step and more precisely between the rising edge of a clock pulse CLK triggering said step and the release step. This first interval of time IT1 makes it possible to release the inputs once the input shift values SHIFT_IN have indeed been propagated in the simple flip-flops FF, i.e. to say on the inputs D of said flip-flops. A problem commonly referred to as the problem of “skew” is avoided. If the clock CLK is activated on the simple flip-flops FF and if in parallel the value at the inputs D of said flip-flops is modified by releasing the inputs DT of the associated selectors S, it is not known what value has been captured in said simple flip-flops FF.

Thus the first interval of time IT1 between the release step and the rising edge of a clock pulse CLK is greater, here by 1 ns, than the time for setting up and holding a flip-flop (normally referred to as “setup time & hold time”), known to those skilled in the art. This setup time varies according to the technology of the flip-flop. In the state of the art, this time is around 0.1 ns.

At time t7, the tester commences a functional cycle.

At time t8, the normal mode is activated, the control pin SE is reset to 0, and at the same time the functional test values NORM_IN are applied to the functional input pins PI.

At time t9, the comparison step CMP_PO is performed between the functional result values NORM_RES obtained and the functional output values NORM_OUT of the test vector V.

At time t10, a clock pulse CLK is given again in order to capture the shift result values SHIFT_RES according to the CAPTURE step, and at time t11 the shift mode is activated once again (SE=1).

At time t12, the 9^{th} step COMP_SCAN is performed. The shift result values SHIFT_RES are compared with the shift output values SHIFT_OUT of the test vector V.

A new clock pulse CLK is applied in order to test the following test vector V, and so on until all the test vectors V are tested.

An additional advantage of the test method according to the invention lies in the fact that, during the same shift mode as that of the step FORCE, the shift result values SHIFT_RES obtained during a previous shift mode are compared with the shift output values SHIFT_OUT of the preceding test vector V of said preceding shift mode, as indicated in FIG. 3, at time t3 (step CMP_SCAN).

Advantageously, the activation of the control pin SE (SE=1) does not take place at the same time as the application of a clock pulse CLK. As indicated in FIG. 3, there also exists a second sufficient time interval IT2 between a rising edge of a clock pulse CLK and a transition of a signal on the control pin SE, i.e. here the setting of the circuit in the shift mode. In the example proposed, this second time interval is preferably taken to be greater than or equal to 10 ns. This also makes it possible to avoid the problems of “skew” explained above.

Thus, by virtue of the test method by simulation presented above, errors are anticipated before the true physical testing of the circuit by the tester, which makes it possible to save considerable time when the integrated circuit is manufactured.

If an error occurs, it may be decided either to continue the simulation in order to have traceability of all the errors, or to stop the simulation in order to seek at once the cause of the error and correct it.

It should be noted that, before all these steps 1 to 9 described above, the following test may be applied to the integrated circuit:

an initialization test. This test applies a set of stimuli to the circuit, which then enters the scan mode i.e. the circuit is in a certain state making it possible to receive the test vectors V;

a scan continuity test. This test verifies that the circuit scan chain is not broken. For this purpose, it maintains the signal SE at 1 and sends a known integrity vector to the input pin SI. This vector has to propagate through the scan chain as far as the output pin SO after a number of clock cycles CLK equal to the longest scan chain that can be found in the circuit;

a test of N test vectors in series. In general, the first 5 to 10 test vectors are taken, which are tested in a scan chain serially, in order to check that the test simulation program is being executed correctly.

As has been seen, the steps of the test method described above are implemented by means of a simulator SIMU. A set of instructions contained in a programming memory of the simulator may cause the simulator SIMU to perform the various steps of the integrated circuit test method described above. The set of instructions may alternatively be loaded into the programming memory by the reading of a data medium such as for example, a disk which contains the set of instructions. The reading may alternatively be carried out by means of a communication network such as, for example, the Internet. In this case a service provider will make the set of instructions available to interested parties.

It should be noted that, subsequently, the same steps are performed on the tester for physically testing the integrated circuit, but entering values serially rather than in parallel into the circuit.

Obviously, the scope of the invention is in no way limited to the embodiments described above, and variations or modifications may be made thereto without for all that departing from the spirit and scope of the invention.

No reference symbol in the present text should be interpreted as limiting said text.

The verb “comprise” and its conjugations should also not be interpreted limitingly, i.e. they should not be interpreted as excluding the presence of steps or elements other than those defined in the description, or as excluding a plurality of steps or elements listed after said verb and preceded by the article “a” or “one”.

1. An integrated circuit test method intended to function in a normal mode and a serialization mode, said circuit comprising a clock (CLK), simple flip-flops (FF) and associated selectors (S), said method using at least one test vector comprising serialized input (SHIFT_IN) and output (SHIFT_OUT) values, characterized in that it comprises the steps of:
setting the circuit in the serialization mode at the start of a clock cycle (CLK),
applying serialized input values (SHIFT_IN) of the test vector (V) in parallel to the selectors (S),
loading said serialized input values (SHIFT_IN) in parallel into said simple flip-flops (FF) associated with said selectors (S),
setting the circuit in the normal mode,
capturing serialized result values (SHIFT_RES) in the flip-flops (FF),
recovering said serialized result values (SHIFT_RES) in said flip-flops (FF) in parallel and comparing them with the serialized output values (SHIFT_OUT) of the test vector (V).

2. An integrated circuit test method as claimed in claim 1, characterized in that it also comprises a step of releasing the selectors (S), which step is performed just after the loading of the serialized input values (SHIFT_IN) into the simple flip-flops (FF).

3. An integrated circuit test method as claimed in claim 2, characterized in that there exists a first interval of time (IT1) between the step of loading the serialized input values (SHIFT_IN) in parallel and the step of releasing the selectors (S), said interval of time (IT1) being greater than a time for setting up and holding a flip-flop (FF).

4. An integrated circuit test method as claimed in claim 3, characterized in that the first interval of time (IT1) exists between a rising edge of a clock pulse (CLK) triggering the loading step and said release step.

5. An integrated circuit test method as claimed in claim 1, characterized in that there exists a second interval of time (IT2) between a rising edge of a clock pulse (CLK) and the setting of the circuit in the serialization mode.

6. An integrated circuit test method as claimed in claim 1, characterized in that in parallel to the application in parallel of the serialized input values (SHIFT_IN) of the test vector (V) to the selectors (S), the serialized result values (SHIFT_RES) obtained during a previous serialization mode are compared with the serialized output values (SHIFT_OUT) of a previous test vector (V).

7. An integrated circuit test method as claimed in claim 1, characterized in that the test vector (V) also comprises functional input values (NORM_IN) and functional output values (NORM_OUT).

8. An integrated circuit test method as claimed in claim 7, characterized in that it also comprises a step of applying functional input values (NORM_IN) of the test vector (V) to the circuit, said step being performed before the circuit is set in the normal mode.

9. An integrated circuit test method as claimed in claim 8, characterized in that it also comprises a step of recovering in parallel functional result values (NORM_RES) from the circuit and of comparing said values with functional output values (NORM_OUT) of the test vector (V), said step being performed after the circuit was set in the normal mode.

10. An integrated circuit test method as claimed in claim 9, characterized in that the step of recovering the functional result values (NORM_RES) takes place before the step of capturing the serialized result values (SHIFT_RES) present in the simple flip-flops (FF).
